(19) United States
(12) Patent Application Publication
(10) Pub. No.: US 2026/0319378 A1
(43) Pub. Date: Oct. 15, 2026

(54) ADJUSTING EFFECTIVE DEPTH OF FOCUS

(71) Applicant: Applied Materials, Inc., Santa Clara, CA (US)

(72) Inventors: Jong Yun Kim, Gyeonggi-do (KR); Kim Seong Sim, Singapore (SG); Jen-Yu Fang, Shanghai (CN)

(21) Appl. No.: 18/859,114

(22) PCT Filed: Jan. 5, 2024
(86) PCT No.: PCT/CN2024/070896

§ 371 Date: Oct. 22, 2024

(51) Int. Cl. G03F 7/00; G03F 7/20

(52) U.S. Cl. CPC G03F 7/70333; G03F 7/2002; G03F 7/2022; G03F 7/70025; G03F 7/70466

(57) ABSTRACT

A method includes causing a laser component to perform a first set patterning operations in a pixel shape on a substrate at a first focal plane without offset. The method further includes causing the laser component to perform a second set of the patterning operations in the pixel shape on the substrate at a second focal plane with a positive offset.

### RELATED APPLICATIONS

This application claims the benefit under 35 U.S.C. § 371 of International Patent Application No. PCT/CN2024/070896, filed Jan. 5, 2024, the contents of which are incorporated by reference in their entirety.

### TECHNICAL FIELD

The present disclosure relates to effective depth of focus in manufacturing systems, such as processing chambers, and in particular to adjusting effective depth of focus in processing chambers.

### BACKGROUND

In substrate processing and other electronics processing, processing chambers are used to perform substrate processing operations. Different components are controlled in the processing chambers to perform substrate processing operations.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In an aspect of the disclosure, a method includes causing a laser component to perform a first set patterning operations in a pixel shape on a substrate at a first focal plane without offset. The method further includes causing the laser component to perform a second set of the patterning operations in the pixel shape on the substrate at a second focal plane with a positive offset.

In another aspect of the disclosure, a non-transitory machine-readable storage medium storing instructions which, when executed cause a processing device to perform operations including causing a laser component to perform a first set patterning operations in a pixel shape on a substrate at a first focal plane without offset. The operations further include causing the laser component to perform a second set of the patterning operations in the pixel shape on the substrate at a second focal plane with a positive offset.

In another aspect of the disclosure, a system includes memory and a processing device coupled to the memory. The processing device is to cause a laser component to perform a first set patterning operations in a pixel shape on a substrate at a first focal plane without offset. The processing device is further to cause the laser component to perform a second set of the patterning operations in the pixel shape on the substrate at a second focal plane with a positive offset.

### BRIEF DESCRIPTION OF THE DRAWINGS

The present disclosure is illustrated by way of example, and not by way of limitation in the figures of the accompanying drawings.

FIG. 1A is a block diagram illustrating an exemplary system architecture, according to certain embodiments.

FIG. 1B illustrates an upper schematic view of a digital photolithography system, according to certain embodiments.

FIGS. 2A-D illustrate patterning operations performed by laser components, according to certain embodiments.

FIGS. 3A-B illustrate patterning operations of laser components, according to certain embodiments.

FIG. 4 is a flow diagram of a method associated with adjusting effective field of focus, according to certain embodiments.

FIG. 5 is a block diagram illustrating a computer system, according to certain embodiments.

### DETAILED DESCRIPTION

Described herein are technologies directed to adjusting (e.g., enhancing) effective depth of focus.

In substrate processing and other electronics processing, processing chambers are used to perform substrate processing operations. Different components are controlled in the processing chambers to perform substrate processing operations. For example, a laser component can be controlled to perform etching patterns on a substrate.

Conventionally, in substrate processing, components (e.g., laser components) are controlled using a fixed depth of focus (DOF). For advanced packaging (AP) application of digital lithography tool (DLT) in substrate processing, higher DOF is used due to thick film thickness (e.g., photo-resist (PR) film thickness) and coarse topography. The use of certain optics (e.g., high numerical aperture (NA) optics) can be limited.

Conventionally, there are many patterning issues in DLT that are related to resolution, critical dimension (CD) uniformity, Mura (e.g., irregularity, lack of uniformity), etc. These can be caused by components being out of focus (e.g., unexpected local out-of-focus motion or temporary out-of-focus motion). Substrates may have local topography variations. Actuators may control a focal length between the projection lens and the substrate over a long range (e.g., on the fly). This is not available for local topography (e.g., short-range variation) which increases the patterning issues of local topography. This causes errors in producing substrates, reduces yield, reduces substrate quality, and causes waste of materials and energy.

The devices, systems, and methods disclosed herein provide solutions to these and other shortcomings of conventional systems.

In some embodiments, a processing device causes a laser component to perform a first set of patterning operations in a pixel shape on a substrate at a first focal plane without offset and subsequently causes the laser component to perform a second set of the patterning operations in the pixel shape on the substrate at a second focal plane with a positive offset. The patterning operations may be a two-cycle exposure and the pixel shape may be a rotated square pixel shape.

In some embodiments, a processing device causes a laser component to perform a first set of patterning operations in a pixel shape on a substrate at a first focal plane without offset, subsequently causes the laser component to perform a second set of the patterning operations in the pixel shape on the substrate at a second focal plane with a positive offset, and subsequently causes the laser component to perform a third set of patterning operations in the pixel shape on the substrate at a third focal plane with a negative offset. The patterning operations may be a three-cycle exposure and the pixel shape may be a rotated hexagon pixel shape.

Aspects of the present disclosure result in technological advantages. By causing the patterning operations at different focal planes and in the same pixel shape, the present disclosure has less patterning issues than conventional systems. This causes better patterning for short-range variations changes in local topography of substrates, causes less errors in producing substrates, increases yield, increases substrate quality, and reduces waste of materials and energy.

Although some embodiments of the present disclosure are described in relation to a laser component that performs a patterning operation on a substrate, the present disclosure, in some embodiments, is applied to other components (e.g., other types of components that have a focal plane) that perform one or more operations (e.g., patterning operation, non-patterning operation, imaging, etc.).

Although some embodiments of the present disclosure are described in relation to two or three sets of patterning operations (e.g., two-or three-cycle exposure), in some embodiments, more than three sets of patterning operations may be used (e.g., more than three-cycle exposure).

Although some embodiments of the present disclosure are described in relation to a single laser component performing two or three sets of patterning operations (e.g., two-or three-cycle exposure), in some embodiments, a first laser component can perform a first set of patterning operations and a second laser component can perform a second set of patterning operations.

As used herein, the term “produce” can refer to producing a final version of a product (e.g., completely processed substrate) or an intermediary version of a product (e.g., partially processed substrate). As used herein, the producing substrates can refer to processing substrates via performance of one or more substrate processing operations.

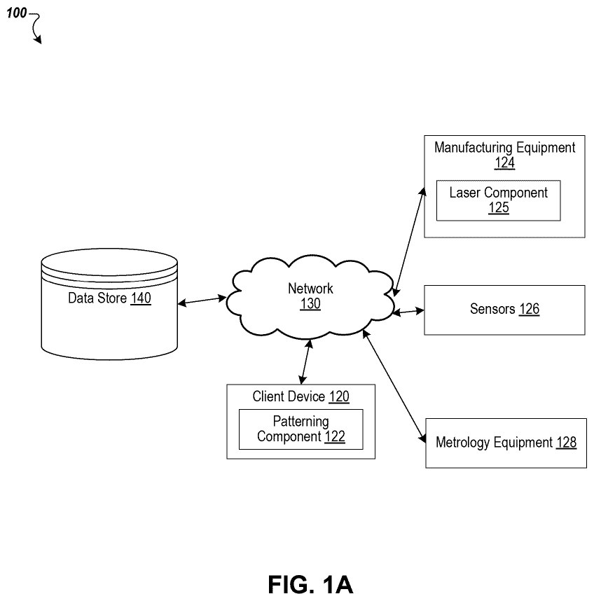

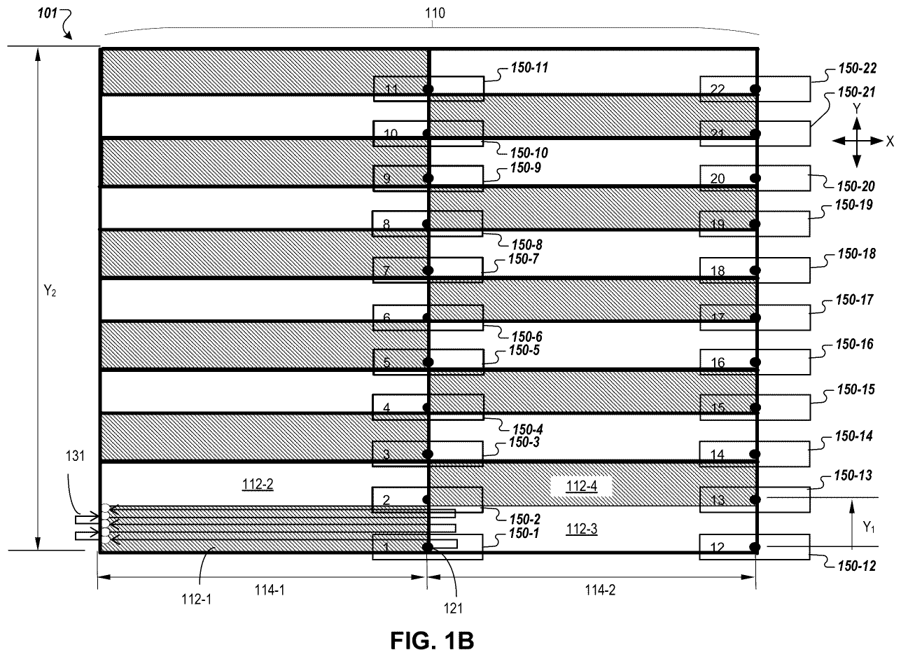

FIG. 1A is a block diagram illustrating an exemplary system 100 (exemplary system architecture), according to certain embodiments. The system 100 includes a client device 120, manufacturing equipment 124, sensors 126, metrology equipment 128, and a data store 140. Manufacturing equipment 124 may include a laser component 125 (e.g., optical imaging unit, etc.). In some embodiments, the client device 120 is a controller of the manufacturing equipment 124 (e.g., of the laser component 125).

In some embodiments, one or more of the client device 120, manufacturing equipment 124, sensors 126, metrology equipment 128, and/or data store 140 are coupled to each other via a network 130 for performing substrate processing operations. In some embodiments, network 130 is a public network that provides client device 120 with access to the data store 140 and/or other publicly available computing devices. In some embodiments, network 130 is a private network that provides client device 120 access to manufacturing equipment 124, sensors 126, metrology equipment 128, data store 140, and other privately available computing devices. In some embodiments, network 130 includes one or more Wide Area Networks (WANs), Local Area Networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, wired network, and/or a combination thereof.

In some embodiments, the client device 120 includes a computing device such as Personal Computers (PCs), laptops, mobile phones, smart phones, tablet computers, netbook computers, etc. In some embodiments, the client device 120 includes a server device. In some embodiments, the client device 120 includes a patterning component 122. Client device 120 includes an operating system that allows users to one or more of consolidate, generate, view, or edit data, provide directives to the manufacturing equipment 124, etc.

In some embodiments, patterning component 122 receives one or more of user input (e.g., via a Graphical User Interface (GUI) displayed via the client device 120), receives sensor data (e.g., from client device 120, from data store 140), etc. In some embodiments, the patterning component 122 controls laser component 125, causes interruption of one or more components, and/or the like. In some embodiments, the patterning component 122 stores data (e.g., user input, sensor data, etc.) in the data store 140.

In some embodiments, the patterning component 122 causes a laser component 125 to perform a first set of patterning operations in a pixel shape on a substrate at a first focal plane without offset and subsequently causes the laser component 125 to perform a second set of the patterning operations in the pixel shape on the substrate at a second focal plane with a positive offset. The patterning operations may be a two-cycle exposure and the pixel shape may be a rotated square pixel shape.

In some embodiments, the patterning component 122 causes a laser component 125 to perform a first set of patterning operations in a pixel shape on a substrate at a first focal plane without offset, subsequently causes the laser component 125 to perform a second set of the patterning operations in the pixel shape on the substrate at a second focal plane with a positive offset, and subsequently causes the laser component 125 to perform a third set of patterning operations in the pixel shape on the substrate at a third focal plane with a negative offset. The patterning operations may be a three-cycle exposure and the pixel shape may be a rotated hexagon pixel shape.

In some embodiments, the manufacturing equipment 124 (e.g., cluster tool) is part of a substrate processing system (e.g., integrated processing system). The manufacturing equipment 124 includes one or more of a controller, an enclosure system (e.g., substrate carrier, front opening unified pod (FOUP), auto teach FOUP, process kit enclosure system, substrate enclosure system, cassette, etc.), a side storage pod (SSP), an aligner device (e.g., aligner chamber), a factory interface (e.g., equipment front end module (EFEM)), a load lock, a transfer chamber, one or more processing chambers (e.g., multi-slot processing chambers), a robot arm (e.g., disposed in the transfer chamber, disposed in the front interface, etc.), and/or the like. The enclosure system, SSP, and load lock mount to the factory interface and a robot arm disposed in the factory interface is to transfer content (e.g., substrates, process kit rings, carriers, validation wafer, etc.) between the enclosure system, SSP, load lock, and factory interface. The aligner device is disposed in the factory interface to align the content. The load lock and the processing chambers mount to the transfer chamber and a robot arm disposed in the transfer chamber is to transfer content (e.g., substrates, process kit rings, carriers, validation wafer, etc.) between the load lock, the processing chambers, and the transfer chamber. In some embodiments, the manufacturing equipment 124 includes components of substrate processing systems. In some embodiments, the sensor data include parameters of processes performed by components of the manufacturing equipment 124 (e.g., radio frequency (RF) generation, lifting, etching, heating, cooling, transferring, processing, flowing, cleaning, etc.). In some embodiments, the manufacturing equipment 124 includes laser component 125 (e.g., of a processing chamber) that is configured to perform patterns on substrates.

In some embodiments, the sensors 126 provide sensor data (e.g., sensor values) associated with manufacturing equipment 124. In some embodiments, the sensors 126 include one or more of an RF sensor, a lift sensor, an imaging sensor (e.g., camera, image capturing device, etc.), a pressure sensor, a temperature sensor, a flow rate sensor, a spectroscopy sensor, and/or the like. In some embodiments, the sensor data used for equipment health and/or product health (e.g., product quality). In some embodiments, the sensor data is received over a period of time. In some embodiments, sensors 126 provide sensor data such as values of one or more of image data, leak rate, temperature, pressure, flow rate (e.g., gas flow), pumping efficiency, spacing (SP), High Frequency Radio Frequency (HFRF), electrical current, power, voltage, and/or the like.

In some embodiments, the metrology equipment 128 (e.g., imaging equipment, spectroscopy equipment, ellipsometry equipment, etc.) is used to determine metrology data (e.g., inspection data, image data, spectroscopy data, ellipsometry data, material compositional, optical, or structural data, etc.) corresponding to substrates produced by the manufacturing equipment 124 (e.g., substrate processing equipment). In some examples, after the manufacturing equipment 124 processes substrates, the metrology equipment 128 is used to inspect portions (e.g., layers) of the substrates. In some embodiments, the metrology equipment 128 performs scanning acoustic microscopy (SAM), ultrasonic inspection, x-ray inspection, and/or computed tomography (CT) inspection. In some examples, after the manufacturing equipment 124 deposits one or more layers on a substrate, the metrology equipment 128 is used to determine quality of the processed substrate (e.g., thicknesses of the layers, uniformity of the layers, interlayer spacing of the layer, and/or the like). In some embodiments, the metrology equipment 128 includes an image capturing device (e.g., SAM equipment, ultrasonic equipment, x-ray equipment, CT equipment, and/or the like).

In some embodiments, the data store 140 is memory (e.g., random access memory), a drive (e.g., a hard drive, a flash drive), a database system, or another type of component or device capable of storing data. In some embodiments, data store 140 includes multiple storage components (e.g., multiple drives or multiple databases) that span multiple computing devices (e.g., multiple server computers). In some embodiments, the data store 140 stores one or more of sensor data from sensors 126, metrology data from metrology equipment 128, instructions generated by patterning component 122, and/or the like.

In some embodiments, a “user” is represented as a single individual. However, other embodiments of the disclosure encompass a “user” being an entity controlled by users and/or an automated source. In some examples, a set of individual users federated as a group of administrators is considered a “user.”

Although embodiments of the disclosure are discussed in terms of causing laser component to perform patterning operations of a substrate, in some embodiments, the disclosure can also be generally applied to controlling components.

FIG. 1B illustrates an upper view of a digital photolithography system (“system”) 101 (e.g., manufacturing equipment 124 of FIG. 1A), according to certain embodiments. System 101 includes one or more exposure units 150 (e.g., EYE, laser component 125 of FIG. 1A).

As shown, the system 101 includes a stage assembly 110 including a base (e.g., a granite base), a stage and a substrate disposed on the stage. The substrate may be a glass plate, a wafer, a printed circuit board (PCB), or other type of substrate. The substrate may correspond to or be positioned in a digital lithography printing or scanning area having a number of scan regions, including scan regions 112-1 through 112-4. The left portion of the stage assembly 110 corresponds to a first bridge 114-1 above the stage assembly 110 and the right portion of the stage assembly 110 corresponds to a second bridge 114-2 above the stage assembly 110. Exposure units are attached to the bridges 114-1 and 114-2. In some embodiments, the length of each bridge 114-1 and 114-2 can range between about 500 millimeters (mm) and about 1000 mm. For example, the length of each bridge 114-1 and 114-2 can be about 750 mm.

The substrate can include a photoresist material disposed on a material to be etched. The photoresist material can be a positive photoresist material (i.e., where a portion of the photoresist material that is exposed to light becomes soluble to a photoresist developer) or a negative photoresist material (i.e., where a portion of the photoresist material that is exposed to light becomes insoluble to a photoresist developer). By removing designated portions of the photoresist material, a photoresist pattern can be formed. In some embodiments, the material to be etched is a conductive material (e.g., metal). For example, the conductive material can be molybdenum. After the designated regions of the photoresist material are removed, the now-exposed material can be etched in accordance with the photoresist pattern. For example, wiring can be formed during the etch process. Alternatively, the patterned material can itself be photosensitive, eliminating the need to add a photoresist layer and performing the following etch process.

To perform the photoresist patterning, the system 101 further includes a first column of digital lithography exposure units 150 (“exposure units”) hanging from the first bridge 114-1 and a second column of exposure units 150 hanging from the second bridge 114-2. For example, the first column of exposure units 150 includes exposure units 150-1 through 150-11 and the second column of exposure units includes exposure units 150-12 through 150-22. Thus, in this illustrative example, there are 22 total exposure units 150 shown. However, the number of exposure units shown in FIG. 1B should not be considered limiting, and the system 101 can include any suitable number of exposure units 150.

Each exposure unit 150 can include a lens assembly 121 that can project an image onto the photoresist material of the substrate. Each lens assembly 121 is shown adjacent to a bottom-right corner of its associated scan region. For example, a lens assembly 121 of exposure unit 150-1 is associated with the scan region 112-1. In some embodiments, each lens assembly 121 is about 4 mm tall and about 3 mm wide. However, each lens assembly 121 can have any suitable dimensions.

During a digital lithography process, each exposure unit 150 is moved relative to the substrate to expose a region (e.g., a rectangular region) of the substrate to electromagnetic radiation such as light (e.g., ultraviolet light, near-ultraviolet light, etc.). This may include moving the exposure units 150 and/or moving the substrate. During scanning, the exposure units 150 expose respective scan regions, in accordance with a programmed scan path. Instead of having the exposure units move above the stage assembly 110, the stage assembly 110 can move in the X-Y direction underneath the exposure units 150 in accordance with the programmed scan path. Since the field-of-view of a lens assembly (e.g., lens assembly 121) can be smaller than its associated scan region (e.g., scan region 112-1), the stage assembly 110 may have to move back and forth repeatedly until the entire scan region (e.g., scan region 112-1) is printed. The lens assembly 121 is projected to scan the scan region 112-1, except for the first and last scans where trimming may occur based on the definition of the scan region 112-1. The greater the number of exposure units 150, the fewer scans that may be performed, which can correspond to higher throughput.

Each exposure unit 150 can be responsible for a different scan region, which may or may not overlap with the adjacent scan regions of other exposure units 150. To avoid abrupt transitions from a first scan region to a second scan region adjacent to the first scan region (either attached to the same bridge or to a different bridge), the exposure unit 150 corresponding to the first scan region can encroach into the second scan region. Similarly, the exposure unit 150 corresponding to the second scan region can encroach into the first scan region. For example, exposure unit 150-1 can encroach into scan region 112-2 and/or scan region 112-3, and exposure unit 150-2 can encroach into scan region 112-1 and/or scan region 112-4.

In an example, a path 131 of the exposure unit 150-1 (e.g., lens assembly 121-1) is illustratively depicted. The path 131 proceeds in a snake-like fashion. More specifically, during scanning, the stage assembly 110 moves in the X direction (i.e., from right to left) across the scan region 112-1, during which time the exposure unit 150-1 patterns a line across the scan region 112-1. The stage assembly 110, upon reaching the left edge of the scan region 112-1, moves in the Y-direction (i.e., up), and then moves in the X-direction (i.e., from left to right) to pattern another line across the scan region 112-1. The path 131 proceeds in this snake-like fashion until reaching the opposite end of the scan region 112-1, at which point a full image has been patterned on the substrate. The image can then be developed for substrate etching. The distance of stage travel in the Y-direction during scanning, “Y₁”, can be any suitable distance. In some embodiments, Y₁ can range between about 150 mm and about 180 mm. For example, Y₁ can be about 164 mm. The scan distance in the X direction for each exposure unit corresponds to the length of the bridges 114-1 and 114-2 in embodiments. The total width of the scan regions, “Y₂”, can be any suitable width. In some embodiments, “Y₂” can range between about 1600 mm and about 2000 mm. For example, Y₂ can be about 1800 mm. The travel distance for each scan (e.g., in the X-direction) can be different due to differences in substrate size. For example, in some embodiments, the substrate includes an 8-inch round wafer. As another example, in some embodiments, the substrate includes a 12-inch round wafer.

The scanning process shown in FIG. 1B can be used to create a display (e.g., a flat panel display) in embodiments. In some embodiments, the display is a liquid-crystal display (LCD).

In some embodiments, system 101 includes one or more exposure units 150 (i.e., EYEs, one or more of exposure units 150-1 to 150-22). In some embodiments, system 101 includes a movable platform that sits beneath the exposure units 150 that moves in the x-y-z direction (relative to the one or more exposure units 150). In some embodiments, system 101 includes one or more a movable support (i.e., a rotation assembly) to which one or more of the exposure units 150 are attached that adjusts the angle of the exposure units 150 relative to the platform (where rotation is about a z axis). In some embodiments, the system 101 is configured to rotate the exposure unit 150 (e.g., EYE) so that an angle of a mirror array of the exposure unit 150 (e.g., EYE) matches an angle of the platform. In some embodiments, each exposure unit 150 (e.g., EYE) has its own rotation device, and the rotations of the exposure units 150 (e.g., EYEs) are matched so that instead of having a different patterning set of parameters for each of the exposure units 150 (e.g., EYEs), the exposure units 150 (e.g., EYEs) all share the same set of parameters.

The one or more exposure units 150 may be a digital micro-mirror device (DMD) configured to focus patterned light onto a substrate (e.g., pixel-by-pixel).

In some embodiments, system 101 (e.g., a processing device of system 101) causes an exposure unit 150 to perform a first set of patterning operations in a pixel shape on a substrate at a first focal plane without offset and subsequently causes the exposure unit 150 to perform a second set of the patterning operations in the pixel shape on the substrate at a second focal plane with a positive offset. The patterning operations may be a two-cycle exposure and the pixel shape may be a rotated square pixel shape.

In some embodiments, system 101 (e.g., a processing device of system 101) causes an exposure unit 150 to perform a first set of patterning operations in a pixel shape on a substrate at a first focal plane without offset, subsequently causes the exposure unit 150 to perform a second set of the patterning operations in the pixel shape on the substrate at a second focal plane with a positive offset, and subsequently causes the exposure unit 150 to perform a third set of patterning operations in the pixel shape on the substrate at a third focal plane with a negative offset. The patterning operations may be a three-cycle exposure and the pixel shape may be a rotated hexagon pixel shape.

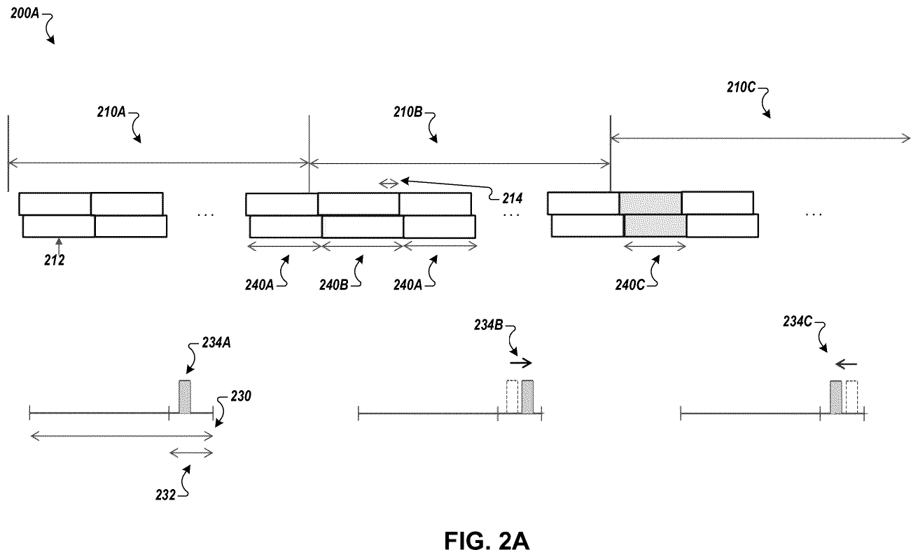

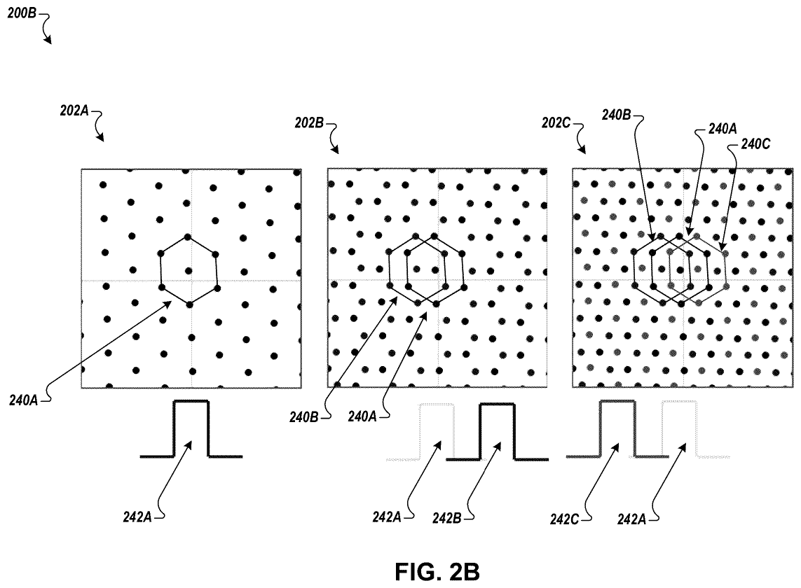

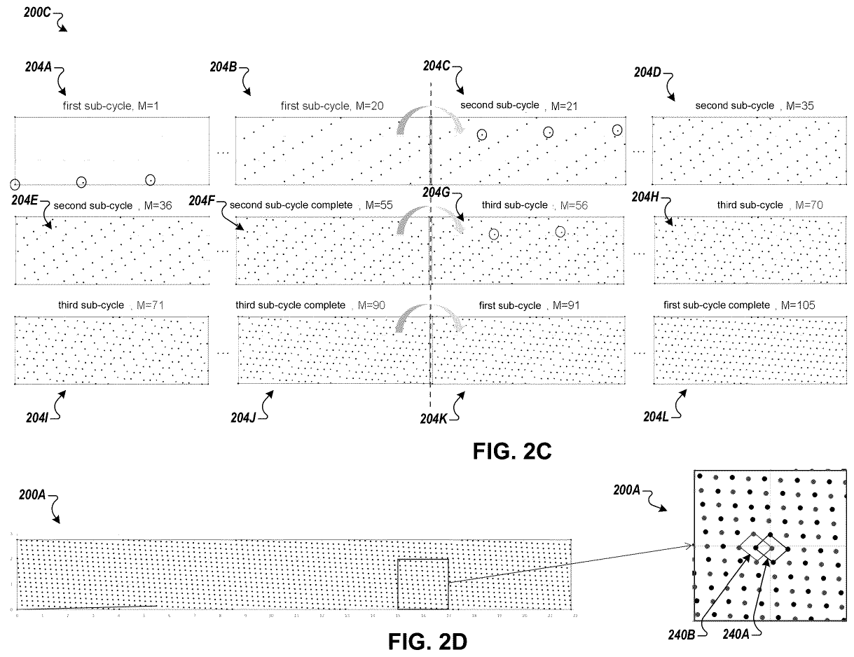

FIGS. 2A-G illustrate patterning operations 200A-D performed by laser components (e.g., laser component 125 of FIG. 1A, exposure unit 150 of FIG. 1B), according to certain embodiments.

For advanced packaging (AP) applications of digital lithography (DLT), higher DOF may be used due to thick photoresist (PR) film thickness and course topography. Use of high numerical aperture (NA) of the optics (e.g., how much light the optics can collect) may be limited.

Conventionally, there may be patterning issues in DLT customer fields, such as those related to resolution, critical dimension (CD) uniformity, Mura (e.g., irregularity, lack of uniformity), or for one or more reasons for which the cause is not clarified.

Unexpected local or temporary out-of-focus motion may be a factor of those issues.

Conventionally, there may be a trade-off between minimum feature resolution and DOF, that may be expressed as:

Minimum feature resolution=k₁*(λ/(NA)); and

DOF=k₂*(λ/(NA²)),

where k₁ and k₂ are process capability factors, λ refers to the exposure wavelength, and NA is the numerical aperture of the optics.

For DLT, laser components that have different magnifications for exposure may be used. For example, first magnification of laser component with high DOF and low resolution may be used for AP (e.g., thick PR thickness), a second magnification (e.g., higher than the first magnification) of laser component with high resolution and low DOF may be used for AP (e.g., display), and/or a third magnification (e.g., higher than the first and/or second magnification) of laser component with high resolution may be used for display (e.g., thin PR thickness).

In AP process, dry films may be used as PR layer and thickness may be over 20 μm depending on product types. In some products, local topography variation can use more tightened DOF control (e.g., glass interposer).

A substrate may pass with a constant span speed under laser component (e.g., an optical imaging unit, EYE, laser component 125 of FIG. 1A, exposure unit 150 of FIG. 1B), which may be rotated by theta with respect to the scan direction. The pattern may have a dotting position in unit pattern size (e.g., rasterization).

Responsive to DMD (e.g., of a laser component, laser component 125 of FIG. 1A, exposure unit 150 of FIG. 1B) having a rotation angle (θ) and scan pitch (ΔX) that are arbitrary, conventionally the accumulated pixel distribution may not be uniform. This may cause substrate irregularities and defects.

To have periodicity in the shot distribution (e.g., of the patterning operation), DMD rotation angle may be rational number, the starting position may be the same with the end position within unit micromirror area, and one cycle distance (e.g., total distance under available DMD) may be a multiple of the scan pitch.

For a fixed DMD rotation angle, the multiplicity may determine the scan pitch (e.g., scan speed*pulse period) and the pattern interface scheme.

Conventionally, an interlacing scheme may be diverse and complicated depending on selected parameters and intermediate stages may not show unform pixel distribution.

Piezo actuators (e.g., about 125 Hertz (Hz) to about 175 Hz) may be used to control the optimal focal length between the projection lens (e.g., of a laser component) and a substrate over a long rage on-the-fly, but conventionally may not be available for local topography (e.g., short range variation).

To increase effective DOF, the principle of multiple focal plans may be used with actuators (e.g., steppers, piezo actuators) for different tools (e.g., laser component). Multi-focal plans may be obtained by passing the substrate multiple times with different focal planes or by repeating the periodic interlacing cycle multiple times in one pass.

Conventionally, the overlapping exposure position can degrade patterning resolution due to reduced pixel density.

A dotting procedure (e.g., patterning operation) can be repeated multiple times. Different focal planes can be applied for each cycle to increase effective DOF. Conventionally, multiple shots may be exposed to the same position which may result in the patterning resolution becoming degraded due to the reduced pixel density.

In some embodiments, a periodic offset may be used with particular (e.g., optimal) pixel shapes. To keep the uniform and compact pixel distribution and enhance DOF at the same time, an offset may be imposed to the scan pitch for each cycle with different focal planes. The combined whole pixel distribution may meet a threshold pattern fidelity (e.g., have a good pattern fidelity). Particular pixel shapes (e.g., optimal pixel shapes, shape formed by multiple points of a patterning operation) may be used based on the number of cycles.

Referring to FIG. 2A, a patterning operation 200A (e.g., of laser component 125 of FIG. 1A, exposure unit 150 of FIG. 1B) may have a first set 210A (e.g., first sub-cycle) of the patterning operation 200A, a second set 210B (e.g., second sub-cycle) of the patterning operation 200A, and/or a third set 210C (e.g., next full cycle) of the patterning operation 200A. One or more of the sets 210 (e.g., cycle, sub-cycle) may have a pattern that has a unit pattern size 212 and an offset 220. The cycle of second set 210B may have a pattern including a distance 222A (e.g., ΔX), a distance 222B that is distance 222A plus offset 220 (e.g., ΔX+offset), and the distance 222A (e.g., ΔX). The cycle 210C may have a pattern including a distance 222A minus offset 220 (e.g., ΔX-offset).

Each set 210 may have a pattern period 230 that has an available exposure period 232 and an exposure 234. In some embodiments, the set 210A may have an exposure 234A (e.g., biased timing), the set 210B may have an exposure 234B (e.g., delayed pulsing), and the set 210C may have an exposure 234 °C (e.g., back to original timing).

Referring to FIG. 2B, patterning operations 200B (e.g., of laser component 125 of FIG. 1A, exposure unit 150 of FIG. 1B) include enhanced effective DOF that has a pixel distribution (e.g., uniform pixel distribution, substantially uniform pixel distribution, etc.).

A laser component may perform a first set 202A of patterning operations 200B in a pixel shape 240A (e.g., a hexagon, a substantial hexagon) on a substrate at a first focal plane without offset 242A. For the first set 202A (in pixel shape 240A), the following equation may be used:

Focus=f

The laser component may perform a second set 202B of patterning operations 200B in the pixel shape 240B (e.g., a hexagon, a substantial hexagon, same as pixel shape 240A, substantially the same as pixel shape 240A) on the substrate at a second focal plane with a positive offset 242B.

The second set 202B may be performed subsequent to the first set 202A. The first set 202A may be Focus=f and the following equation may be used for the second set 202B (in pixel shape 240B):

Focus=f+Δf

The laser component may perform a third set 202C of patterning operations 200B in the pixel shape 240C (e.g., a hexagon, a substantial hexagon, same as pixel shape 240A and/or 240B, substantially the same as pixel shape 240A and/or 240B) on the substrate at a third focal plane with a negative offset 242C.

The third set 202C may be performed subsequent to the second set 202B (that is performed subsequent to the first set 202A). The first set 202A may be Focus=f, the second set 202B may be Focus=f+Δf, and the following equation may be used for the third set 202C (in pixel shape 240C):

Focus=f+2*(Δf)

Referring to FIG. 2C, patterning operations 200C (e.g., of laser component 125 of FIG. 1A, exposure unit 150 of FIG. 1B) include different sets 204.

FIG. 2C may illustrate examples of three sub-cycles that have three different focal planes. In some embodiments, after a first threshold of exposure of patterning operations, a positive offset is applied and after a second threshold of exposure of patterning operations, a negative offset is applied, and after a third threshold of exposure of patterning operations, the offset is set back to zero.

Set 204A may be a first sub-cycle at a first point in time (e.g., M=1). Set 204B may be the first sub-cycle at a second point in time (e.g., M=20).

Set 204C may be a second sub-cycle at a third point in time (e.g., M=21). Set 204D may be the second sub-cycle at a fourth point in time (e.g., M=35). Set 204E may be the second sub-cycle at a fifth point in time (e.g., M=36). Set 204F may be the second sub-cycle at a sixth point in time (e.g., M=55, second sub-cycle complete).

Set 204G may be a third sub-cycle at a seventh point in time (e.g., M=56). Set 204H may be the third sub-cycle at an eighth point in time (e.g., M=70). Set 204I may be a third sub-cycle at a nineth point in time (e.g., M=71). Set 204J may be the third sub-cycle at a tenth point in time (e.g., M=90, third sub-cycle complete). Set 204K may be the first sub-cycle at an eleventh point in time (e.g., M=91). Set 204L may be the first sub-cycle at a twelfth point in time (e.g., M=105, first sub-cycle complete).

Referring to FIG. 2D, in some embodiments, patterning operations may two sub-cycles. Conventionally, there is no periodic offset and two different focal planes are overlapped in the position which causes low pixel density and reduced pattern resolution. In some embodiments of the present disclosure, an offset is applied where two different focal planes are uniformly mixed and the combined pixel distribution is uniform and compact. For example, in FIG. 2D, patterning operations 200D includes a first set of patterning operations 200D in a pixel shape 240A on a substrate at a first focal plane without offset (e.g., Focus =f) and a second set of patterning operations 200D in a pixel shape 240B on the substrate at a second focal plane with a positive offset (e.g., Focus =f +Af).

Fixed DOF may be used and multiple interlacing cycle may be used to enhance effective DOF (e.g., for AP application). To sustain uniform and compact pixel distribution, a periodic offset with pixel shapes (e.g., optimal pixel shapes) may be used to maintain substantially uniform and dense pixel distribution. In the case of two cycle exposure, rotated square pixel shape may be used. In the case of three cycle exposure, a rotated hexagon pixel shape may be used to maintain substantially uniform and dense pixel distribution. By increasing effective DOF: 1) the patterning operations may become easy and robust; 2) the trade-off relation between resolution and DOF may be mitigated; and/or 3) pattern resolution may be improved with little or no pattern rate degradation.

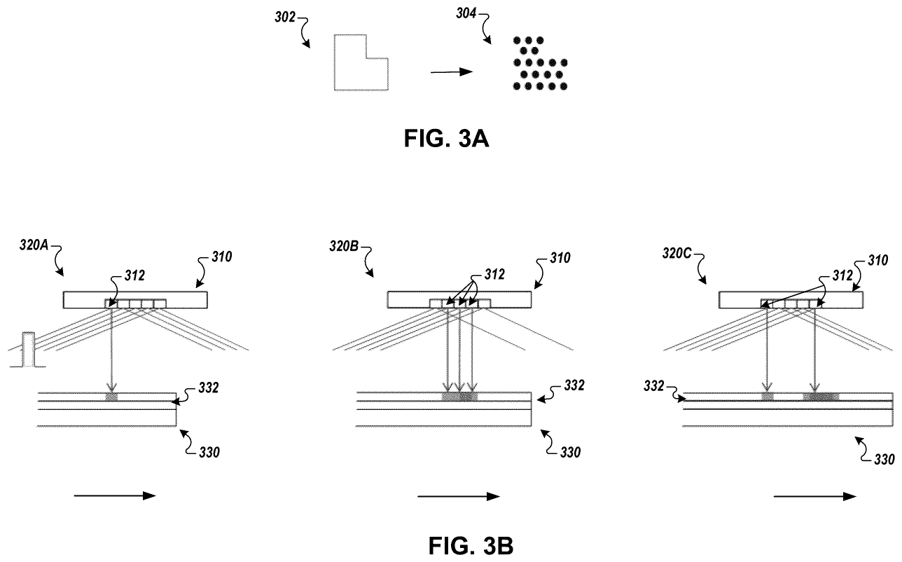

Referring to FIG. 3A, in some embodiments, a file 302 (e.g., GDS file) is transformed into a bitmap image 304 (e.g., may undergo rasterization) to be used for performing patterning operations (e.g., by laser component 125 of FIG. 1A, exposure unit 150 of FIG. 1B) on a substrate.

Referring to FIG. 3B, a Spatial Light Modulator (SLM) 310 (e.g., laser component 125 of FIG. 1A, client device 120 of FIG. 1A, exposure unit 150 of FIG. 1B) may replace a conventional photo mask (e.g., to be a maskless photo lithography). A substrate 330 coated with PR 332 may move under the SLM 310 with a constant scan speed (e.g., scan speed of about 150 millimeters per second (mm/s) to about 300 mm/s) while receiving periodic laser exposure. The pulse duration on the substrate 330 coated with PR 332 may be short enough to freeze the stage motion (e.g., a few micro-seconds).

The SLM 310 may include DMDs 312 that may be selectively controlled to direct the patterning operations (e.g., according to one or more methods of the present disclosure).

In a first shot 320A (e.g., first set of patterning operations), one or more first DMDs 312 may be actuated to reflect one or more patterning operations onto the substrate 330.

In a second shot 320B (e.g., second set of patterning operations), one or more second DMDs 312 may be actuated to reflect one or more patterning operations onto the substrate 330.

In a third shot 320C (e.g., third set of patterning operations), one or more third DMDs 312 may be actuated to reflect one or more patterning operations onto the substrate 330.

A processing logic may control the DMDs 312, SLM 310, and/or substrate 330 to process the substrate 330 (e.g., by performing method 400).

In some embodiments, the processing logic may rotate one or more of the DMDs 312. When a DMD 312 is rotated, the coordinate of each mirror centroid is changed by the rotation transformation matrix to cause one or more of the DMDs 312 to cause patterning operations on the substrate 330.

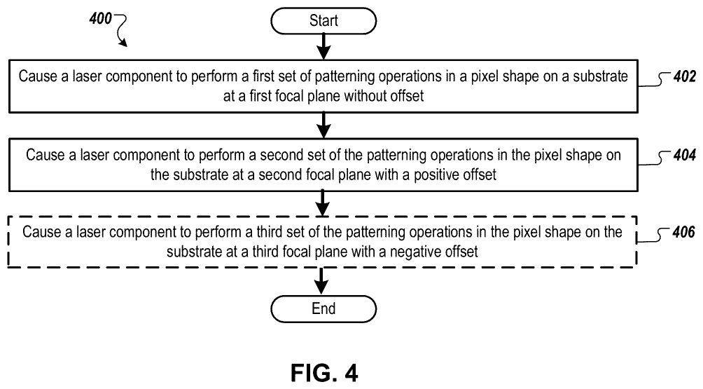

FIG. 4 is a flow diagram of a method 400 associated with adjusting effective field of focus, according to certain embodiments. In some embodiments, method 400 is performed by processing logic that includes hardware (e.g., circuitry, dedicated logic, programmable logic, microcode, processing device, etc.), software (such as instructions run on a processing device, a general purpose computer system, or a dedicated machine), firmware, microcode, or a combination thereof. In some embodiments, method 400 is performed, at least in part, by client device 120. In some embodiments, a non-transitory storage medium stores instructions that when executed by a processing device (e.g., of client device 120 of FIG. 1A, etc.), cause the processing device to perform one or more operations of method 400.

For simplicity of explanation, method 400 is depicted and described as a series of operations. However, operations in accordance with this disclosure can occur in various orders and/or concurrently and with other operations not presented and described herein. Furthermore, in some embodiments, not all illustrated operations are performed to implement method 400 in accordance with the disclosed subject matter. In addition, those skilled in the art will understand and appreciate that method 400 could alternatively be represented as a series of interrelated states via a state diagram or events.

Referring to FIG. 4, in some embodiments, at block 402 the processing logic causes a laser component (e.g., optical imaging unit, EYE, laser component 125 of FIG. 1A, exposure unit 150 of FIG. 1B, etc.) to perform a first set of patterning operations in a pixel shape on a substrate at a first focal plane without offset. In some embodiments, the causing of the laser component to perform the first set of the patterning operations at the first focal plane is responsive to causing a piezo actuator to position the laser component in a first position associated with the first focal plane.

At block 404, processing logic causes a laser component (e.g., laser component 125 of FIG. 1A, exposure unit 150 of FIG. 1B, the same laser component as block 402, a different laser component than block 402) to perform a second set of the patterning operations in the pixel shape on the substrate at a second focal plane with a positive offset. In some embodiments, the causing of the laser component to perform the second set of the patterning operations at the second focal plane is responsive to causing the piezo actuator to position the laser component in a second position associated with the second focal plane. In some embodiments, wherein the causing of the laser component to perform the second set of the patterning operations includes applying the positive offset to a scan pitch of the laser component.

In some embodiments, for a method including blocks 402-404 (not block 406), the patterning operations is a two-cycle exposure and the pixel shape is a rotated square pixel shape.

In some embodiments, at block 406, processing logic causes a laser component (e.g., laser component 125 of FIG. 1A, exposure unit 150 of FIG. 1B, the same laser component as block 402 and/or block 404, a different laser component than block 402 and/or block 404) to perform a third set of the patterning operations in the pixel shape on the substrate at a third focal plane with a negative offset. In some embodiments, the causing of the laser component to perform the third set of the patterning operations at the third focal plane is responsive to causing the piezo actuator to position the laser component in a third position associated with the third focal plane. In some embodiments, wherein the causing of the laser component to perform the second set of the patterning operations includes applying the negative offset to a scan pitch of the laser component.

In some embodiments, the positive offset is a first quantity of offset in a positive direction and the negative offset is the first quantity of offset in a negative direction.

In some embodiments, for a method including blocks 402-406, the patterning operations is a three-cycle exposure and the pixel shape is a rotated hexagon pixel shape.

In some embodiments, the substrate has a threshold photo-resist layer thickness and a threshold DOF.

In some embodiments, the method includes causing a laser component to perform sets of patterning operations on a substrate with periodic offset in a pixel shape (e.g., rotated square pixel shape, rotated hexagon pixel shape).

In some embodiments, the method enhances (e.g., increases) effective depth of focus. In some embodiments, the method is used for applied DLT for AP application. Conventional fixed DOF can be vulnerable to local topography or temporal out-of-focus motion and can be a potential cause of field patterning issues. The present disclosure may apply multiple focal planes and periodic offset to the scan pitch for each sub-cycle to sustain uniform and compact pixel density. The present disclosure may enhance effective DOF to cause the process to be easy and robust, mitigate the trade-off relation between resolution and DOF, and increase pattern resolution with reduced or no degradation in pattern rate compared to conventional systems.

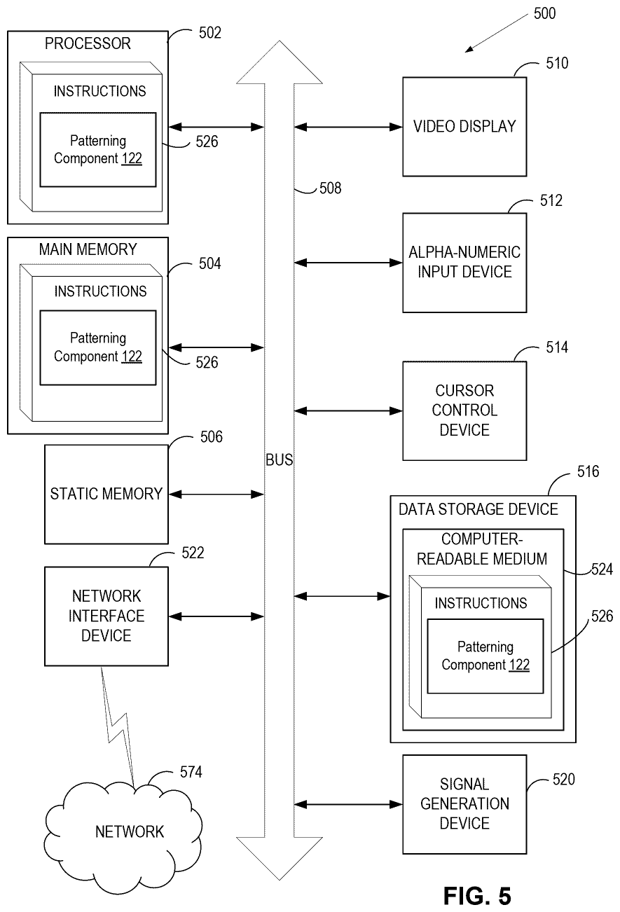

FIG. 5 is a block diagram illustrating a computer system 500, according to certain embodiments. In some embodiments, the computer system 500 is client device 120.

In some embodiments, computer system 500 is connected (e.g., via a network, such as a Local Area Network (LAN), an intranet, an extranet, or the Internet) to other computer systems. In some embodiments, computer system 500 operates in the capacity of a server or a client computer in a client-server environment, or as a peer computer in a peer-to-peer or distributed network environment. In some embodiments, computer system 500 is provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 500 includes a processing device 502, a volatile memory 504 (e.g., Random Access Memory (RAM)), a non-volatile memory 506 (e.g., Read-Only Memory (ROM) or Electrically-Erasable Programmable ROM (EEPROM)), and a data storage device 516, which communicate with each other via a bus 508.

In some embodiments, processing device 502 is provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

In some embodiments, computer system 500 further includes a network interface device 522 (e.g., coupled to network 574). In some embodiments, computer system 500 also includes a video display unit 510 (e.g., an LCD), an alphanumeric input device 512 (e.g., a keyboard), a cursor control device 514 (e.g., a mouse), and a signal generation device 520.

In some implementations, data storage device 516 includes a non-transitory computer-readable storage medium 524 on which store instructions 526 encoding any one or more of the methods or functions described herein, including instructions encoding components of FIG. 1A (e.g., patterning component 122, predictive component 114, etc.) and for implementing methods described herein.

In some embodiments, instructions 526 also reside, completely or partially, within volatile memory 504 and/or within processing device 502 during execution thereof by computer system 500, hence, in some embodiments, volatile memory 504 and processing device 502 also constitute machine-readable storage media.

While computer-readable storage medium 524 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

In some embodiments, the methods, components, and features described herein are implemented by discrete hardware components or are integrated in the functionality of other hardware components such as application-specific integrated circuits (ASICs), field programmable gate arrays (FPGAs), digital signal processors (DSPs), or similar devices. In some embodiments, the methods, components, and features are implemented by firmware modules or functional circuitry within hardware devices. In some embodiments, the methods, components, and features are implemented in any combination of hardware devices and computer program components, or in computer programs.

Unless specifically stated otherwise, terms such as “causing,” “performing,” “determining,” “continuing,” “identifying,” “providing,” “receiving,” “updating,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. In some embodiments, the terms “first,” “second,” “third,” “fourth,” etc. as used herein are meant as labels to distinguish among different elements and do not have an ordinal meaning according to their numerical designation.

Examples described herein also relate to an apparatus for performing the methods described herein. In some embodiments, this apparatus is specially constructed for performing the methods described herein, or includes a general-purpose computer system selectively programmed by a computer program stored in the computer system.

Such a computer program is stored in a computer-readable tangible storage medium.

The methods and illustrative examples described herein are not inherently related to any particular computer or other apparatus. In some embodiments, various general-purpose systems are used in accordance with the teachings described herein. In some embodiments, a more specialized apparatus is constructed to perform methods described herein and/or each of their individual functions, routines, subroutines, or operations. Examples of the structure for a variety of these systems are set forth in the description above.

The above description is intended to be illustrative, and not restrictive.

Although the present disclosure has been described with references to specific illustrative examples and implementations, it will be recognized that the present disclosure is not limited to the examples and implementations described. The scope of the disclosure should be determined with reference to the following claims, along with the full scope of equivalents to which the claims are entitled.

1. A method comprising:
causing a laser component to perform a first set of a plurality of patterning operations in a pixel shape on a substrate at a first focal plane without offset; and
causing the laser component to perform a second set of the plurality of patterning operations in the pixel shape on the substrate at a second focal plane with a positive offset.

2. The method of claim 1, wherein:
the plurality of patterning operations is a two-cycle exposure; and
the pixel shape is a rotated square pixel shape.

3. The method of claim 1 further comprising causing the laser component to perform a third set of patterning operations in the pixel shape on the substrate at a third focal plane with a negative offset.

4. The method of claim 3, wherein:
the positive offset is a first quantity of offset in a positive direction; and
the negative offset is the first quantity of offset in a negative direction.

5. The method of claim 3, wherein:
the plurality of patterning operations is a three-cycle exposure; and
the pixel shape is a rotated hexagon pixel shape.

6. The method of claim 1, wherein the substrate has a threshold photo-resist layer thickness and a threshold depth of focus (DOF).

7. The method of claim 1, wherein:
the causing of the laser component to perform the first set of the plurality of patterning operations at the first focal plane is responsive to causing a piezo actuator to position the laser component in a first position associated with the first focal plane; and
the causing of the laser component to perform the second set of the plurality of patterning operations at the second focal plane is responsive to causing the piezo actuator to position the laser component in a second position associated with the second focal plane.

8. The method of claim 1, wherein the causing of the laser component to perform the second set of the plurality of patterning operations comprises applying the positive offset to a scan pitch of the laser component.

9. A non-transitory machine-readable storage medium storing instructions which, when executed cause a processing device to perform operations comprising:
causing a laser component to perform a first set of a plurality of patterning operations in a pixel shape on a substrate at a first focal plane without offset; and
causing the laser component to perform a second set of the plurality of patterning operations in the pixel shape on the substrate at a second focal plane with a positive offset.

10. The non-transitory machine-readable storage medium of claim 9, wherein:
the plurality of patterning operations is a two-cycle exposure; and
the pixel shape is a rotated square pixel shape.

11. The non-transitory machine-readable storage medium of claim 9, the operations further comprising causing the laser component to perform a third set of patterning operations in the pixel shape on the substrate at a third focal plane with a negative offset.

12. The non-transitory machine-readable storage medium of claim 11, wherein:
the positive offset is a first quantity of offset in a positive direction; and
the negative offset is the first quantity of offset in a negative direction.

13. The non-transitory machine-readable storage medium of claim 11, wherein:
the plurality of patterning operations is a three-cycle exposure; and
the pixel shape is a rotated hexagon pixel shape.

14. The non-transitory machine-readable storage medium of claim 9, wherein the substrate has a threshold photo-resist layer thickness and a threshold depth of focus (DOF).

15. The non-transitory machine-readable storage medium of claim 9, wherein:
the causing of the laser component to perform the first set of the plurality of patterning operations at the first focal plane is responsive to causing a piezo actuator to position the laser component in a first position associated with the first focal plane; and
the causing of the laser component to perform the second set of the plurality of patterning operations at the second focal plane is responsive to causing the piezo actuator to position the laser component in a second position associated with the second focal plane.

16. A system comprising:
memory; and
a processing device coupled to the memory, the processing device to:
cause a laser component to perform a first set of a plurality of patterning operations in a pixel shape on a substrate at a first focal plane without offset; and
cause the laser component to perform a second set of the plurality of patterning operations in the pixel shape on the substrate at a second focal plane with a positive offset.

17. The system of claim 16, wherein:
the plurality of patterning operations is a two-cycle exposure; and
the pixel shape is a rotated square pixel shape.

18. The system of claim 16, wherein the processing device is further to cause the laser component to perform a third set of patterning operations in the pixel shape on the substrate at a third focal plane with a negative offset, wherein the positive offset is a first quantity of offset in a positive direction, the negative offset is the first quantity of offset in a negative direction, the plurality of patterning operations is a three-cycle exposure, and the pixel shape is a rotated hexagon pixel shape.

19. The system of claim 16, wherein the substrate has a threshold photo-resist layer thickness and a threshold depth of focus (DOF).

20. The system of claim 16, wherein:
causing the laser component to perform the first set of the plurality of patterning operations at the first focal plane is responsive to the processing device causing a piezo actuator to position the laser component in a first position associated with the first focal plane; and
causing the laser component to perform the second set of the plurality of patterning operations at the second focal plane is responsive to the processing device causing the piezo actuator to position the laser component in a second position associated with the second focal plane.
